(19) United States
(12) Patent Application Publication
(10) Pub. No.: US 2024/0320186 A1
(43) Pub. Date: Sep. 26, 2024

(54) Metal-Configurable Multi-Protocol PHY

(71) Applicant: YorChip, Inc., San Ramon, CA (US)

(72) Inventor: Kashmira JOHAL, San Ramon, CA (US)

(73) Assignee: YorChip, Inc., San Ramon, CA (US)

(21) Appl. No.: 18/599,087

(22) Filed: Mar. 7, 2024

Related U.S. Application Data
(60) Provisional application No. 63/454,273, filed on Mar. 23, 2023.
(60) Provisional application No. 63/577,081, filed on Mar. 28, 2023.

(51) Int. Cl. G06F 15/80; G06F 13/42; G06F 15/82; H01L 27/02; H02H 9/04

(52) U.S. Cl. CPC G06F 15/8023; G06F 13/4282; G06F 15/825; H01L 27/0248; H02H 9/046

(57) ABSTRACT

An IC, e.g., a bare die, includes an array of bit-slice tiles. Each bit-slice tile has a ground circuit, a supply circuit, an ESD protection circuit, and a bit-transmit circuit and/or bit-receive circuit for a communication protocol, such as UCIe and/or BoW. Bondpads, using an interconnect layer that can be at or near the top of the metal stack, are placed over one or more bit-slice tiles, and can connect with one or more of the circuits in these one or more of the bit-slice tiles.

To configure the IC, one selects a communication protocol, bump pitch, and number of data bits. Based on the bump pitch, the number of bit-slice tiles per data bits is determined, and tiles are grouped for each bondpad to be used. In each group, the bondpad is created in a top interconnect layer, and connected with a circuit in a bit-slice in the group.

### CROSS REFERENCES

This application claims priority from U.S. provisional patent application Ser. No. 63/577,081, entitled “Metal-Configurable Multi-Protocol PHY”, filed on Mar. 28, 2023, and U.S. provisional patent application Ser. No. 63/454,273, entitled “Novel Multi-Protocol PHY for die to die application with programmable protocol and bump pitch”, filed on Mar. 23, 2023. The priority applications are hereby incorporated by reference, as if it is set forth in full in this specification.

Each publication, patent, and/or patent application mentioned in this specification is herein incorporated by reference in its entirety to the same extent as if each individual publication and/or patent application was specifically and individually indicated to be incorporated by reference.

### BACKGROUND

### Technical Field

The disclosed implementations relate generally to electrical couplings and methods used in integrated circuits (ICs), and in particular to those for interfacing ICs that are physically coupled, such as bare dice mounted next to or on top of each other.

### Context

The subject matter discussed in this section should not be assumed to be prior art merely as a result of its mention in this section. Similarly, a problem mentioned in this section or associated with the subject matter provided as background should not be assumed to have been previously recognized in the prior art. The subject matter in this section merely represents different approaches, which in and of themselves can also correspond to implementations of the claimed technology.

Chiplets are bare (semiconductor) dice, usually with a limited but specialized functionality, that are positioned next to, on top of, or below other bare dice to which they are physically and electrically coupled. Combining different bare dice in a single multichip module (MCM) has several advantages. For example, a chiplet whose functionality has already been proven may be combined with a new large system-on-a-chip (SoC) IC, which might risk being unusable if the function were integrated incorrectly. The chiplet may bring functionality that is hard to achieve in the manufacturing process used for the SoC. For example, an SoC that must be optimized for high-performance computing may use an advanced manufacturing process that has been optimized for fast digital circuits, but that is ill-suited (functionally or economically) for wireless communications. A chiplet may provide the wireless communications functionality in a manufacturing process optimized for radio-frequency circuits. Similarly, chiplets providing memory, power amplification, power management, optical communication, and other functions may enhance the capabilities of an SoC.

### BRIEF DESCRIPTION OF THE DRAWINGS

This patent document or its application file includes one or more color drawings. The U.S. Patent and Trademark Office (USPTO) will provide a copy of this patent or patent application publication with color drawings upon request and payment of required fees. The color drawings also may be available at patentcenter.uspto.gov for this patent application via the Supplemental Content tab.

The technology will be described with reference to the drawings, in which:

FIG. 1 illustrates an example system with die-to-die interfaces.

FIG. 2 shows an example transmit bit-slice and an example receive bit-slice.

FIG. 3 illustrates an example bit-slice tile.

FIG. 4 illustrates relative sizes of some relevant areas assigned to bondpads and their spacing.

FIG. 5A illustrates an example array of bit-slice tiles in a stacked arrangement (straight columns).

FIG. 5B illustrates an example array of bit-slice tiles in a staggered arrangement (zig-zag columns).

FIG. 6A illustrates an example of a bondpad located next to a bit-slice tile with whose supply voltage coupling circuit it is coupled.

FIG. 6B illustrates an example of a bondpad located next to a bit-slice tile with whose first communication protocol bit-transmit circuit it is coupled.

FIG. 7 illustrates an example array of bit-slice tiles on top of which are bondpads for large bumps, each occupying nine bit-slice tiles.

FIG. 8 illustrates an example array of bit-slice tiles on top of which are bondpads for small bumps, each occupying a single bit-slice tile, and coupled with a neighboring bit-slice tile.

FIG. 9 illustrates examples of a wide range of bump pitches supported by an array of bit-slice tiles.

FIG. 10 illustrates a flow diagram for an example method of configuring an IC that includes an array of bit-slice tiles.

In the figures, like reference numbers may indicate functionally similar elements. The systems and methods illustrated in the figures, and described in the Detailed Description below, may be arranged and designed in a wide variety of different implementations. Neither the figures, nor the Detailed Description, are intended to limit the scope as claimed. Instead, they merely represent examples of different implementations of the technology.

### DETAILED DESCRIPTION

Chiplets are bare (semiconductor) dice, usually with a limited but specialized functionality, that are positioned next to, on top of, or below other bare dice to which they are physically and electrically coupled. Combining different bare dice in a single multichip module (MCM) has several advantages. For example, a chiplet whose functionality has already been proven may be combined with a new large system-on-a-chip (SoC) IC, which might risk being unusable if the function were integrated incorrectly. The chiplet may bring functionality that is hard to achieve in the manufacturing process used for the SoC. For example, an SoC that must be optimized for high-performance computing may use an advanced manufacturing process that has been optimized for fast digital circuits, but that is ill-suited (functionally or economically) for wireless communications. A chiplet may provide the wireless communications functionality in a manufacturing process optimized for radio-frequency circuits. Similarly, chiplets providing memory, power amplification, power management, optical communication, and other functions may enhance the capabilities of an SoC.

Often, such functionality is also available as predesigned functional blocks that can be licensed and integrated into the SoC design. However, SoCs are manufactured by various foundries, at various process nodes, process variations, and metal stacks. When a pre-designed functional block is available, it is often for the wrong foundry, the wrong process node, the wrong process version, and/or the wrong metal stack. Redesign can be unfeasible for a variety of reasons, including cost, schedule, and risk. Chiplets don't suffer from these complications. They need to be designed once and can be combined with other bare dice regardless of their respective manufacturing processes. Hence, the cost of a chiplet can potentially be lower than that of a predesigned functional block.

However, chiplets need to interface with the SoCs or other bare dice that they attach to. Such interfacing can often happen via a standard interface protocol such as UCIe, PCIe, Bunch-of-Wires (BoW), and other protocols. This means that to be able to be used with multiple SoCs (in multiple products), a chiplet may need to support multiple protocols and packaging technologies. Electrical connections may be made via bumps or copper pillars. Currently, a popular spacing of bumps (the bump pitch or pad pitch) is 130 microns. Advanced ICs may work with a bump pitch of 40 microns. Over time, the industry may move to 10-micron bump pitches or smaller.

The present technology supports easy and cost-effective customization for a chiplet between multiple protocols and multiple bump pitches.

### Terminology

As used herein, the phrase “one of” should be interpreted to mean exactly one of the listed items. For example, the phrase “one of A, B, and C” should be interpreted to mean any of: only A, only B, or only C.

As used herein, the phrases “at least one of” and “one or more of” should be interpreted to mean one or more items. For example, the phrase “at least one of A, B, or C” or the phrase “one or more of A, B, or C” should be interpreted to mean any combination of A, B, and/or C. The phrase “at least one of A, B, and C” means at least one of A and at least one of B and at least one of C.

Unless otherwise specified, the use of ordinal adjectives “first”, “second”, “third”, etc., to describe an object, merely refers to different instances or classes of the object and does not imply any ranking or sequence.

The terms “comprising” and “consisting” have different meanings in this patent document. An apparatus, method, or product “comprising” (or “including”) certain features means that it includes those features but does not exclude the presence of other features. On the other hand, if the apparatus, method, or product “consists of” certain features, the presence of any additional features is excluded.

The term “coupled” is used in an operational sense and is not limited to a direct or an indirect coupling. “Coupled to” is generally used in the sense of directly coupled, whereas “coupled with” is generally used in the sense of directly or indirectly coupled. Coupled in an electronic system may refer to a configuration that allows a flow of information, signals, data, or physical quantities such as electrons between two elements coupled to or coupled with each other. In some cases, the flow may be unidirectional, in other cases the flow may be bidirectional or multidirectional. Coupling may be galvanic (in this context meaning that a direct electrical connection exists), capacitive, inductive, electromagnetic, optical, or through any other process allowed by physics.

The term “connected” is used to indicate a direct connection, such as electrical, optical, electromagnetic, or mechanical, between the things that are connected, without any intervening things or devices.

The term “configured” to perform a task or tasks is a broad recitation of structure generally meaning having circuitry that performs the task or tasks during operation. As such, the described item can be configured to perform the task even when the unit/circuit/component is not currently on or active. In general, the circuitry that forms the structure corresponding to configured to may include hardware circuits, and may further be controlled by switches, fuses, bond wires, metal masks, firmware, and/or software. Similarly, various items may be described as performing a task or tasks, for convenience in the description. Such descriptions should be interpreted as including the phrase configured to.

As used herein, the term “based on” is used to describe one or more factors that affect a determination. This term does not foreclose the possibility that additional factors may affect the determination. That is, a determination may be solely based on specified factors or based on the specified factors as well as other, unspecified factors. Consider the phrase “determine A based on B”. This phrase specifies that B is a factor that is used to determine A or that affects the determination of A. This phrase does not foreclose that the determination of A may also be based on some other factor, such as C. This phrase is also intended to cover an implementation in which A is determined based solely on B. The phrase based on is thus synonymous with the phrase based at least in part on.

The terms “substantially”, “close”, “approximately”, “near”, and “about” refer to being within minus or plus 10% of an indicated value, unless explicitly specified otherwise.

The following terms or acronyms used herein are defined at least in part as follows:

A “bondpad” in the context of this document is an area in a top interconnect layer of an IC that is electrically coupled with a circuit in the IC, and exposed in a manner that a bond wire or a bump can be attached to it to electrically couple the circuit in the IC with circuits or devices outside of the IC. Bondpads are often located at equal distances from each other, called the pad pitch or bump pitch. In the examples herein, for ease of illustration, the bondpads are shown as within the area covered by the tiles. It is common practice, however, to route the signals to other areas using metal links or “redistribution links” to ease packaging constraints. To be clear, the bondpad may be located outside the tile areas.

“BoW”—bunch of wires—an open die-to-die interface specification by the Open Compute Project.

A “chiplet” is a bare semiconductor die designed to be used in combination with one or more additional semiconductor dice in a multichip module (MCM) to provide specialty functionality that might be costly, difficult, or impossible to integrate in the additional semiconductor dice.

“ESD”—electro-static discharge

“IC”—integrated circuit—a monolithically integrated circuit, i.e., a single semiconductor die which may be delivered as a bare die or as a packaged circuit. For the purposes of this document, the term integrated circuit also includes packaged circuits that include multiple semiconductor dice, stacked dice, or multiple-die substrates. Such constructions are now common in the industry, produced by the same supply chains, and for the average user often indistinguishable from monolithic circuits.

“IO”—input/output

“MCM”—multichip module

A “PHY” is an electronic circuit that implements the physical layer functions of the Open Systems Interconnection (“OSI”) model in a network interface.

“SoC”—system-on-a-chip—a large integrated circuit that combines various functionality, usually including data processing.

“UCIe”—Universal Chiplet Interconnect Express—an open specification for a die-to-die interconnect and serial bus between chiplets.

### IMPLEMENTATIONS

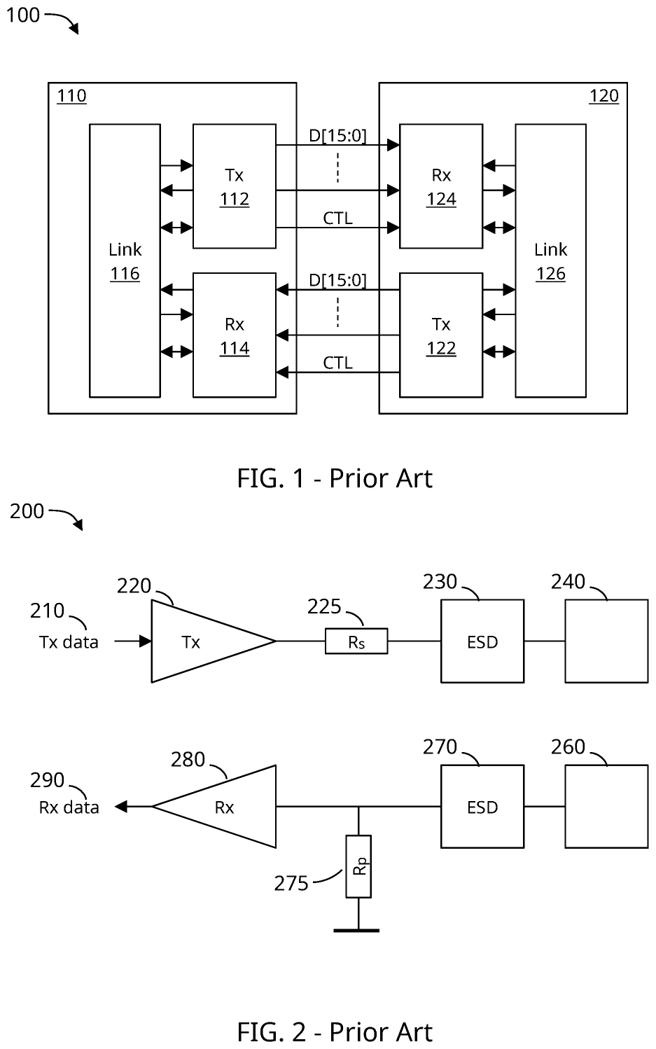

FIG. 1 illustrates an example system 100 with die-to-die interfaces. System 100 includes a first chiplet 110 and a second chip or chiplet 120, connected by data D[15:0] and control (CTL) signals traveling both ways. Other implementations may have fewer or more data signals. And further implementations may have more signals traveling one way or another. The control signals may include clocks, addresses, read or write strobes, and any other signals commonly found in a data bus. First chiplet 110 may include a transmit PHY 112 that implements transmit functionality of a network interface, a receive PHY 114 that implements receive functionality of the network interface, a link layer circuit 116 that implements link layer functionality of the network interface, and other functional blocks. Second chip or chiplet 120 may include a receive PHY 124 that implements receive functionality of the network interface, a transmit PHY 122 that implements transmit functionality of the network interface, a link layer circuit 126 that implements link layer functionality of the network interface, and other functional blocks. In a simultaneous two-way communication protocol (as depicted in FIG. 1), two-way communication requires two sets of data lines D[15:0], as drawn, requiring two bondpads per chiplet per data line pair. In a time-division multiplexed communication protocol, two-way communication can be established using a single set of data lines D[15:0] and requiring only one bondpad per chiplet per data line. Implementations may stack the transmit and receive bondpads as separate blocks next to each other, although they can also pair data lines bit-by-bit. A transmit PHY may include calibration and skew features to get high-quality links at high speeds.

Communication standards used for connecting chiplets, such as UCIe and BoW, may recommend or prescribe certain bump pitches, for example a 130-microns distance between the centers of adjacent bondpads, but they may also leave room for advances in packaging and assembly technology. For example, a standard may support the option of an advanced package that uses a 40-microns bump pitch. In future, the industry may further advance to 10-microns bump pitches. Until now, supporting multiple bump pitches required multiple versions of a product, involving multiple physical implementation cycles, multiple mask sets for prototyping and production, and multiple product validation and qualification cycles. This adds very significantly to the product development cost and schedule, especially with advanced foundry processes where a single mask set can cost millions of dollars.

Additional problems are that some SoC manufacturers deviate from the recommendations made in the communication standards and use other bump pitches; that newer standards may deploy radically different power, ground, and signal locations; and that newer standards may serialize and deserialize data at higher multiples of the on-chip clock speed, for example at four to eight times the on-chip clock speed.

FIG. 2 shows an example 200 of a transmit bit-slice and a receive bit-slice. The transmit bit-slice starts with transmit data 210, which is provided to the transmit controller and PHY 220. The output signal of transmit controller and PHY 220 is forwarded to output bondpad 240, but may pass through an optional series resistor 225 (Rs) to support the characteristic impedance of the transmission line that is naturally included in the die-to-die link, and an electro-static discharge protection circuit (ESD protection circuit 230). The receive bit-slice starts with input bondpad 260, which is followed by ESD protection circuit 270, optional parallel resistor 275 (Rp) to terminate the characteristic impedance of the receive transmission line, and receive PHY and controller 280 to provide receive data 290.

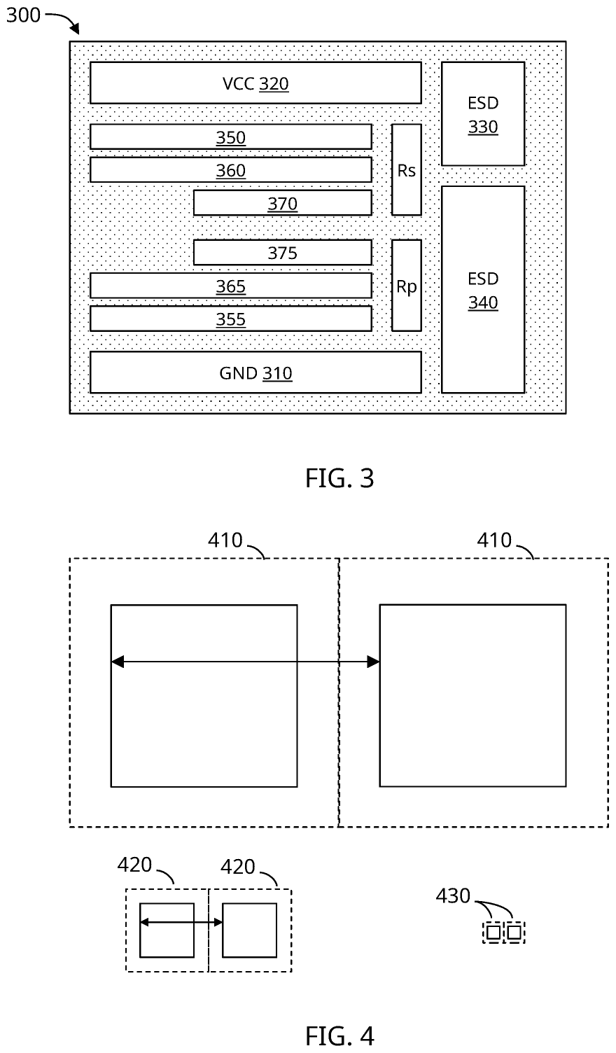

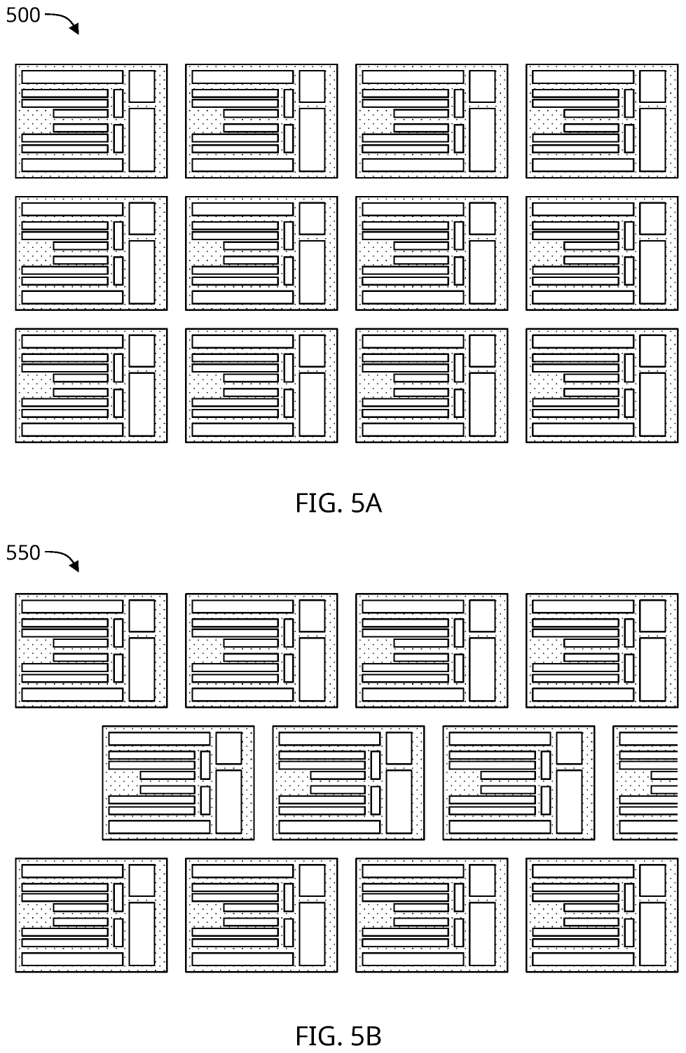

FIG. 3 illustrates an example bit-slice tile 300. A 16-bit one-way die-to-die connection can be made using 16 instances of bit-slice tile 300 plus additional instances for supporting power and ground lines. The bit-slice tiles may be arranged in an array as will be described with reference to FIGS. 5A-B. Bit-slice tile 300 supports connections for one data bit in a standard protocol, for example UCIe or BoW, and may allow configuring for additional protocols. Bit-slice tile 300 supports transmit (Tx) and/or receive (Rx) functions. Further implementations may support further standards, and further functionality. Bit-slice tile 300 includes a kit of elements available to configure a coupling between a bondpad and the elements that provide functionality as needed. Bit-slice tile 300 includes the following elements: ground coupling circuit 310, supply voltage coupling circuit 320, first ESD protection circuit 330, optional second ESD protection circuit 340, first communication protocol bit-transmit circuit 350, first communication protocol bit-receive circuit 355, second communication protocol bit-transmit circuit 360, second communication protocol bit-receive circuit 365, configurable bit-transmit circuit 370, and configurable bit-receive circuit 375. It may further include a line termination series resistor Rs and a line termination parallel resistor Rp. The elements may be coupled to each other using, for example, one or a few interconnect layers near the top of the “metal stack”, i.e., using one or a few of the topmost interconnect layers. Configurable bit-transmit circuit 370 and configurable bit-receive circuit 375 may be configured in the same way, or using lower layer interconnects. An advantage of using only the highest interconnect layers is that for a chiplet that is manufactured using many reticles, only the last few may need to be customized for a specific customer or application, or to support a specific bondpad type, bondpad location, and bondpad pitch. This results in high savings in cost and schedule. Bit-slice tile 300 supports time-division multiplexed communication: both a transmit circuit and a receive circuit are coupled with a single bondpad. It also supports simultaneous two-way communication: either a transmit circuit or a receive circuit is coupled with the bondpad, but two bit-slice tiles are needed and two bondpads are needed. Configurable bit-transmit circuit 370 and configurable bit-receive circuit 375 support transmission and reception of other signals, for example a clock or other CTL signal. Whereas shorter die-to-die connections may require only first ESD protection circuit 330, longer connections, for example via a substrate or PCT, may require the larger or extra protection of second ESD protection circuit 340. The larger or extra ESD protection may slow down the connection, so the shortest connections may also be the fastest connections.

Although configurable bit-transmit circuit 370 and configurable bit-receive circuit 375 are drawn as requiring less die area than other functions, in some implementations they may use the same area as the other functions, or larger areas. Also, some implementations may include extra circuits, such as a phase-locked loop, a clock skew circuit, a clock divider, a calibration circuit, or any other circuit that is useful in a PHY.

Although bit-slice tile 300 is depicted as having a rectangular area that is wide and not very tall, in other implementations a bit-slice tile may be square, or rectangular and tall but not very wide.

FIG. 4 illustrates relative sizes of some relevant areas assigned to bondpads and their spacing. A bondpad pitch may be given as a single distance, implying that the pitch applies both horizontally and vertically, or it may be given as an explicit pair of distances. The pitch includes the size of the bondpad itself, and a clearance area around it. For example, a bondpad pitch of 130 microns means that bondpads 410 (including clearance area) may be arranged in a single row with one bondpad each 130 microns, or in an array with columns of bondpads each 130 microns and rows of bondpads each 130 microns. Staggered arrangements are also possible, as is illustrated in a later figure. Current recommendations for bondpad pitches are 130 microns by 130 microns for standard packaging. Area 420 represents a bondpad plus spacing of 40 by 40 microns for advanced packaging. As packaging technology advances, a future recommendation may move to 10 by 10 microns, as depicted by area 430. Since bondpads may be placed over one or more bit-slice tiles in the technology disclosed herein, a bit-slice tile of 10 by 10 microns supports packaging technology well into the future. A bit-slice tile of 40 by 40 microns supports all current packaging technology.

FIG. 5A illustrates an example array of bit-slice tiles 500 in a stacked arrangement (straight columns and rows). FIG. 5B illustrates an example array of bit-slice 550 tiles in a staggered arrangement (zig-zag columns or rows). Whether stacked or staggered, an implementation provides a “sea of bit-slice tiles” over which bondpads may be positioned as required in a particular application. An advantage of the staggered arrangement is that the smallest possible bondpads will also be staggered, allowing more space between adjacent bumps, which can be substantially round in footprint. Although FIGS. 5A-B suggest that array of bit-slice tiles 500 and array of bit-slice 550 are made up of identical tiles that support both transmit and receive functions, in some implementations an array of bit-slice tiles includes only bit-slice tiles with transmit functions, or only bit-slice tiles with receive functions. And in other implementations, an array of bit-slice tiles may include a mix of bit-slice tiles that only support transmit functions and bit-slice tiles that only support receive functions, for example laid out in a checkerboard pattern, or in alternating rows, or in alternating columns, or in any other pattern.

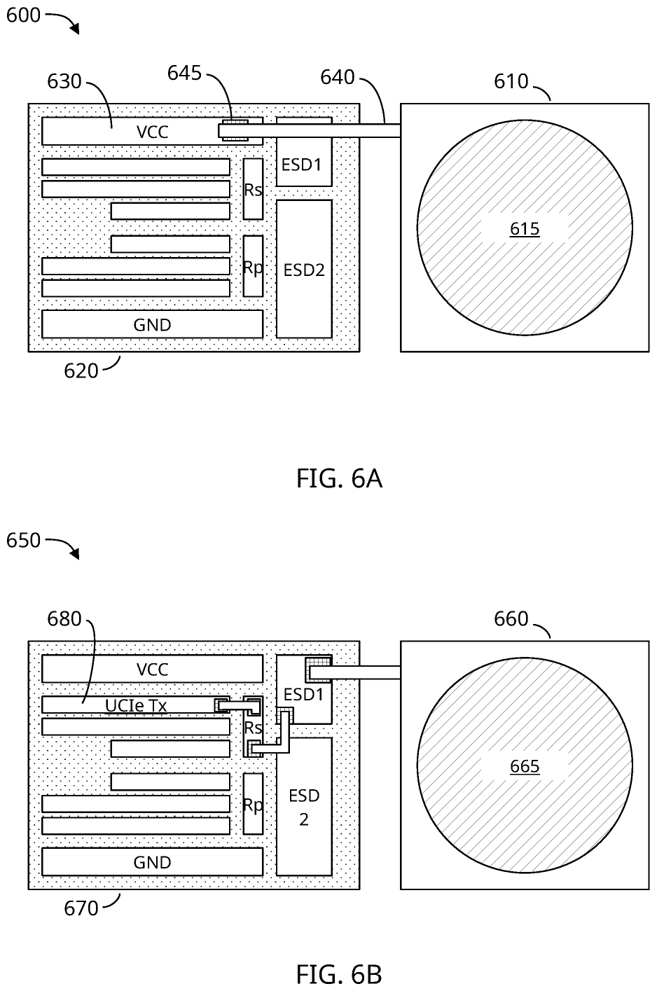

FIG. 6A illustrates an example 600 of a bondpad 610 located next to a bit-slice tile 620 with whose supply voltage coupling circuit 630 it is coupled. Bondpad 610 is drawn next to bit-slice tile 620 to better illustrate connections, but in practical implementations it may also be positioned over bit-slice tile 620. A bump 615 may be attached to bondpad 610 as drawn to provide an electrical coupling with off-chip circuits. From bondpad 610 runs a metal track 640, for example in a top metal layer, to via 645, which provides an electrical coupling through lower interconnect layers down to supply voltage coupling circuit 630.

FIG. 6B illustrates an example 650 of a bondpad 660 located next to a bit-slice tile 670 with whose first communication protocol bit-transmit circuit 680 it is coupled. Bondpad 660 provides a location to attach bump 665. From bondpad 660, a metal track runs to a via above the first ESD protection circuit (ESD1). Another via above ESD1 allows connection of a second metal track, which runs to a via above termination series resistor Rs. Another via above Rs allows connection to a third metal track, which runs to a via above first communication protocol bit-transmit circuit 680. In this example, first communication protocol bit-transmit circuit 680 includes a UCIe bit-transmit circuit. Thus, example 650 shows how a UCIe transmit PHY is connected to an external circuit, via termination resistor Rs, ESD protection circuit ESD1, bondpad 660, and bump 665, using metal tracks that may all be located in a top interconnect layer.

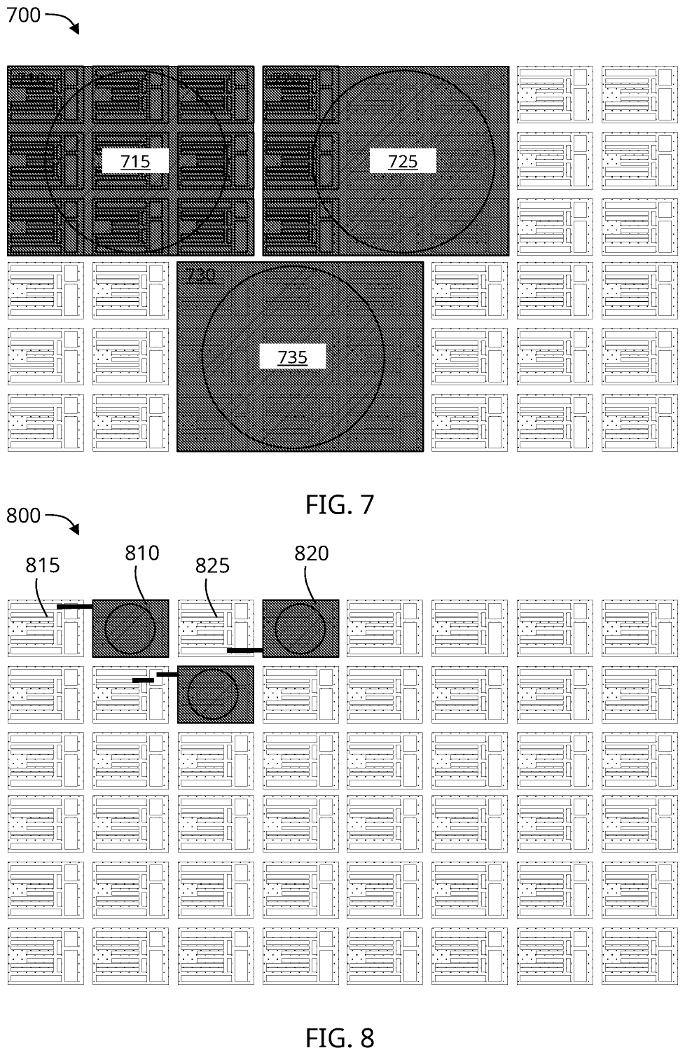

FIG. 7 illustrates an example array of bit-slice tiles 700 on top of which are bondpads for large bumps, each occupying nine bit-slice tiles. This example shows bondpad 710, bondpad 720, and bondpad 730, for bump 715, bump 725, and bump 735, respectively. Although array of bit-slice tiles 700 is arranged in a stacked arrangement (as in FIG. 5A as opposed to FIG. 5B), the positioning of the bondpads can still be close to staggered, leaving more room between the centers of the bumps. Although FIG. 7 shows bondpad 710 located over the group of bit-slice tiles with which it is associated, in other implementations bondpad 710 may be connected with through-silicon-vias (TSVs) and located on the opposing surface of the die, effectively underneath the group of bit-slice tiles with which it is associated.

FIG. 8 illustrates an example array of bit-slice tiles 800 on top of which are bondpads for small bumps, each occupying a single bit-slice tile, and coupled with a neighboring bit-slice tile. In this example, bumps are small enough that two bit-slice tiles are available per bump. As discussed with reference to FIGS. 6A-B, if more bumps are needed, they could each occupy one tile rather than two, and bondpads could connect directly to the tile above which they are located. However, in this example, bondpad 810 is coupled with a supply voltage coupling circuit in bit-slice tile 815, and bondpad 820 is coupled with a ground coupling circuit in bit-slice tile 825. The spacing in-between allows a bondpad in the next row to be staggered, thus again taking advantage of the larger possible distance of the centers of the bumps.

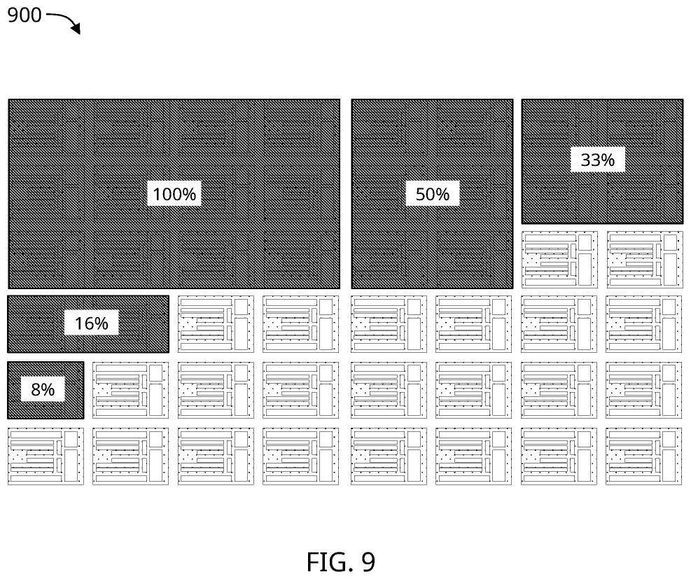

FIG. 9 illustrates examples of a wide range of bump pitches supported by an array of bit-slice tiles 900. For example, a large bondpad covers an area indicated as 100% (twelve bit-slice tiles). A 50% bondpad covers six tiles, a 33% bondpad covers four tiles, and so on. Thus, the concept of a sea of bit-slice tiles, to which connections can be made from an interconnect layer at or near the top of the metal stack, allows economic coupling of custom bondpads of various sizes to various PHY functions that together make up one or more PHYs, where the size, location, and type of bondpad can be chosen, along with the desired communication protocol.

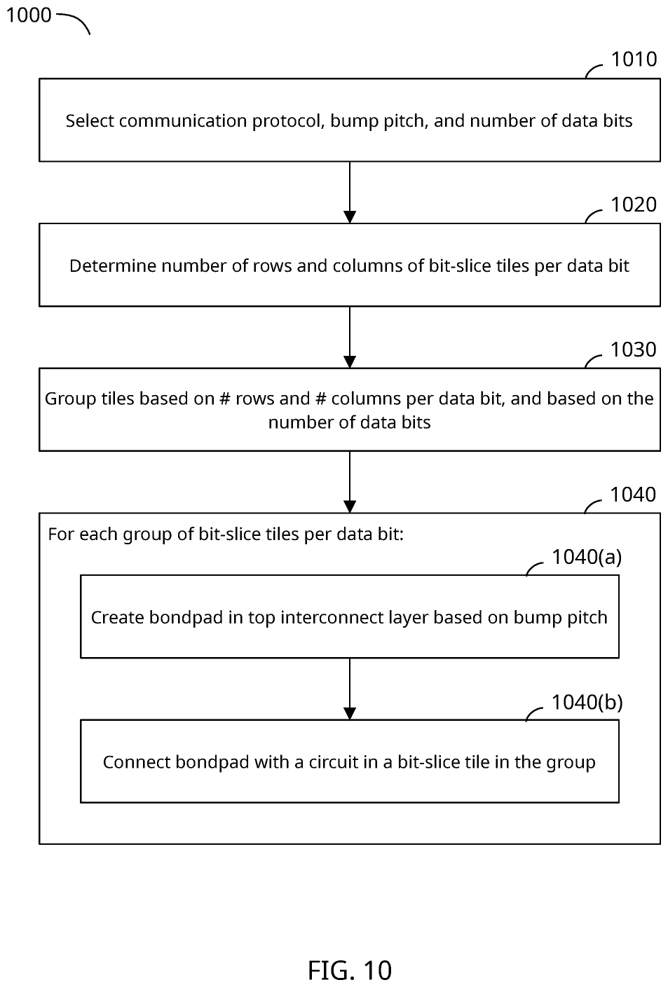

FIG. 10 illustrates a flow diagram for an example method 1000 of configuring an IC that includes an array of bit-slice tiles. Method 1000 comprises the following steps.

Step 1010—selecting a communication protocol, a bump pitch, and a number of data bits. For example, an implementation must provide a 16-bit simultaneous two-way communication BoW PHY for a bump pitch of 40 microns. In this example, there may have to be 32 data bits (16 transmit and 16 receive), 20 power and ground connections, and 4 clock connections, for a total of 56 bondpads.

Step 1020—based on the bump pitch, determining a number of rows and columns of bit-slice tiles per data bit. For example, if a bit-slice tile measures 20 by 20 microns, a bondpad with 40-micron bump pitch occupies the area of four bit-slice tiles (two rows, two columns).

Step 1030—grouping bit-slice tiles in the array of bit-slice tiles into groups according to the number of rows and columns per data bit, and according to the number of data bits. In the example, 56 bondpads occupy the area of 224 bit-slice tiles. The BoW standard may prescribe an arrangement of bondpads in three rows of up to 20 bondpads, thus in the array of bit-slice tiles this can be realized using six rows of bit-slice tiles (three bondpads each occupying two rows of bit-slice tiles), and forty columns of bit-slice tiles (twenty bondpads each occupying two columns of bit-slice tiles) for a total collection of 240 bit-slice tiles. Thus, the PHY bondpad area may cover an effective area of up to the total collection of 240 bit-slice tiles. In some implementations, part of the effective area may be used for on-die decoupling capacitors.

Step 1040—for each group of bit-slice tiles per data bit:

Step 1040(a)—creating a bondpad in a top interconnect layer according to the bump pitch.

Step 1040(b)—electrically coupling the bondpad with a circuit in a bit-slice tile in the group of bit-slices tiles.

### Considerations

Although the description has been described with respect to specific implementations thereof, these specific implementations are merely illustrative, and not restrictive. The description may reference specific structural implementations and methods and does not intend to limit the technology to the specifically disclosed implementations and methods. The technology may be practiced using other features, elements, methods and implementations. Implementations are described to illustrate the present technology, not to limit its scope, which is defined by the claims. Those of ordinary skill in the art recognize a variety of equivalent variations on the description above.

All features disclosed in the specification, including the claims, abstract, and drawings, and all the steps in any method or process disclosed, may be combined in any combination, except combinations where at least some of such features and/or steps are mutually exclusive. Each feature disclosed in the specification, including the claims, abstract, and drawings, can be replaced by alternative features serving the same, equivalent, or similar purpose, unless expressly stated otherwise.

Although the description has been described with respect to specific implementations thereof, these specific implementations are merely illustrative, and not restrictive. For instance, many of the operations can be implemented on a printed circuit board (PCB) using off-the-shelf devices, in a System-on-Chip (SoC), application-specific integrated circuit (ASIC), programmable processor, a coarse-grained reconfigurable architecture (CGRA), or in a programmable logic device such as a field-programmable gate array (FPGA), obviating the need for at least part of any dedicated hardware. Implementations may be as a single chip, or as a multi-chip module (MCM) packaging multiple semiconductor dice in a single package. All such variations and modifications are to be considered within the ambit of the disclosed technology the nature of which is to be determined from the foregoing description.

Any suitable technology for manufacturing electronic devices can be used to implement the circuits of specific implementations, including CMOS, FinFET, GAAFET, BICMOS, bipolar, JFET, MOS, NMOS, PMOS, HBT, MESFET, etc. Different semiconductor materials can be employed, such as silicon, germanium, SiGe, GaAs, InP, GaN, SiC, graphene, etc. Circuits may have single-ended or differential inputs, and single-ended or differential outputs. Terminals to circuits may function as inputs, outputs, both, or be in a high-impedance state, or they may function to receive supply power, a ground reference, a reference voltage, a reference current, or other. Although the physical processing of signals may be presented in a specific order, this order may be changed in different specific implementations. In some specific implementations, multiple elements, devices, or circuits shown as sequential in this specification can be operating in parallel.

It will also be appreciated that one or more of the elements depicted in the drawings/figures can also be implemented in a more separated or integrated manner, or even removed or rendered as inoperable in certain cases, as is useful in accordance with a particular application.

Thus, while specific implementations have been described herein, latitudes of modification, various changes, and substitutions are intended in the foregoing disclosures, and it will be appreciated that in some instances some features of specific implementations will be employed without a corresponding use of other features without departing from the scope and spirit as set forth. Therefore, many modifications may be made to adapt a particular situation or material to the essential scope and spirit.

What is claimed is:

1. An integrated circuit (an IC) including an array of bit-slice tiles, wherein:
a bit-slice tile comprises:
a ground coupling circuit;
a supply voltage coupling circuit;
a first electro-static discharge protection circuit (a first ESD protection circuit); and
at least one of a first communication protocol bit-transmit circuit or a first communication protocol bit-receive circuit.

2. The IC of claim 1, wherein the bit-slice tile further comprises:
a second communication protocol bit-transmit circuit; and/or
a second communication protocol bit-receive circuit.

3. The IC of claim 1, wherein:
the first communication protocol bit-transmit circuit and/or the first communication protocol bit-receive circuit is based on a communication protocol described in a Universal Chiplet Interconnect Express (UCIe) standard.

4. The IC of claim 2, wherein:
the second communication protocol bit-transmit circuit and/or the second communication protocol bit-receive circuit is based on a communication protocol described in a Bunch-of-Wires (BoW) standard.

5. The IC of claim 1, wherein:
the bit-slice tile further comprises a second ESD protection circuit.

6. The IC of claim 1, wherein:
bit-slice tiles in the array are arranged in at least one of a stacked arrangement of rows and/or columns or a staggered arrangement of rows and/or columns.

7. The IC of claim 1, further comprising:
a configurable bit-transmit circuit and a configurable bit-receive circuit.

8. The IC of claim 7, wherein:
the configurable bit-transmit circuit and/or the configurable bit-receive circuit include circuits that can be selected and coupled using one or more interconnect layers.

9. The IC of claim 7, wherein:
the configurable bit-transmit circuit and/or the configurable bit-receive circuit is configurable through customization of one or more interconnect layers.

10. The IC of claim 1, further comprising:
one or more top interconnect layers to configure type, size, and/or location of bondpads.

11. The IC of claim 10, wherein:
a bondpad is located over a group of bit-slice tiles associated with the bondpad, wherein the group of bit-slice tiles includes at least one bit-slice tile.

12. The IC of claim 1, wherein:
the bit-slice tile further comprises a line termination series resistor Rs and/or a line termination parallel resistor Rp.

13. The IC of claim 1, wherein:
the bit-slice tile further comprises a second ESD protection circuit larger than the first ESD protection circuit.

14. A method of configuring an IC including an array of bit-slice tiles, the method comprising:
selecting a communication protocol, a bump pitch, and a number of data bits;
based on the bump pitch, determining a number of rows and columns of bit-slice tiles per data bit;
grouping bit-slice tiles in the array of bit-slice tiles into groups according to the number of rows and columns of bit-slice tiles per data bit, and according to the number of data bits; and
for each group of bit-slice tiles per data bit:
(a) creating a bondpad in a top interconnect layer according to the bump pitch; and
(b) electrically coupling the bondpad with a circuit in a bit-slice tile in the group of bit-slice tiles per data bit.
